(19) United States
(12) Patent Application Publication
(10) Pub. No.: US 2021/0219446 A1
(43) Pub. Date: Jul. 15, 2021

(54) VIBRATION DAMPING AND SHOCK ISOLATION IN TRANSPORTATION TOTE

(71) Applicant: Dell Products L.P., Round Rock, TX (US)

(72) Inventors: James Don CURLEE, Round Rock, TX (US); Steven EMBLETON, Austin, TX (US); Joshua Scott KEUP, Austin, TX (US); Ben John SY, Austin, TX (US)

(73) Assignee: Dell Products L.P., Round Rock, TX (US)

(21) Appl. No.: 16/743,128

(22) Filed: Jan. 15, 2020

(51) Int. Cl. H05K 5/02; B60B 33/04; F16F 15/04

(52) U.S. Cl. CPC H05K 5/0234; F16F 15/046; B60B 33/045

(57) ABSTRACT

An apparatus may include an enclosure that includes a plurality of mounting features that are configured to receive information handling systems, a plurality of casters coupled to the enclosure, and first and second dampers. The first damper may have a first resonance frequency and be disposed such that, when the information handling systems are received in the enclosure, the first damper is coupled between the information handling systems and the plurality of casters. The second damper may have a second, different resonance frequency and be disposed such that, when the information handling systems are received in the enclosure, the second damper is coupled between the information handling systems and the plurality of casters.

### TECHNICAL FIELD

The present disclosure relates in general to information handling systems, and more particularly to management of vibrations and shocks in the transportation of information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Various problems are known in the field of transportation and delivery of information handling systems, particularly in the enterprise context of rack-mounted systems including a plurality of standard-sized server information handling systems. Currently, integrated rack solutions are typically delivered to customers on a wooden pallet with foam (e.g., extruded polystyrene foam) to mitigate shock events. The shipping environment is extremely harsh, and integrated rack solutions can see significant forces, causing damage to the rack or the internal equipment. Further, existing solutions tend to involve large quantities of single-use packing and shipping materials that must be discarded after delivery.

This application is related to U.S. application Ser. No. 16/681,336 (Attorney Docket No. 102450.00614), filed Nov. 12, 2019, which is incorporated by reference herein in its entirety. That application discusses in detail various embodiments of shippable “totes” that may be used as an all-in-one solution to dampen shock events via shock absorbers and/or isolators fully integrated into a server rack.

The present application addresses more specifically the vibrations and/or shocks that may arise during movement of information handling systems in totes or other transportation apparatuses.

Existing solutions typically involve vibration damping with a single degree-of-freedom (DOF) system. Such single DOF systems are able to dampen vibrations only at a single frequency, however. The frequency response of such systems may be spread out somewhat, but it will nevertheless be centered at that single frequency. During a large impact, even a spread-out frequency response may not be sufficient when there are multiple resonances at or near the resonant frequency of an information handling system.

Accordingly, some embodiments of this disclosure may include multiple-DOF damping systems. The use of such disparate types of dampers may allow a single large system resonance to be “split” into two or more smaller resonances.

In these and other embodiments, multiple dampers may be used having different resonance frequencies associated therewith. Such dampers may be arranged in parallel or in series, and they may engage at different loads. For example, dampers having different stiffnesses may be used. In these and other embodiments, dampers may be preloaded such that they do not begin to engage until some threshold load level has been surpassed.

Embodiments of this disclosure may allow the selection of multiple frequencies (e.g., for different loads of information handling systems, different environmental conditions, etc.). For example, a spacing may be selected for the dampers such that dampers may engage at selected weights, or such that a damper engages during impacts, but not during vibrations. In these and other embodiments, a transportation system may be tuned so that vibration frequency peaks typically associated with transit may be efficiently damped out without causing undesirable system resonances.

For purposes of this disclosure, a “damper” may include any of various types of vibration and/or shock attenuation components. For example, shock absorbers, linear dampers, spring isolators, wire rope isolators, elastomeric isolators, air springs, structural damping components, shock casters, etc., may all be considered “dampers.”

The use of techniques according to this disclosure may provide many benefits. It should be noted that for the sake of concreteness, this application describes the use of totes. However, one of ordinary skill in the art will appreciate its applicability to other designs as well, such as standard equipment racks, etc.

It should also be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with vibrations and/or shocks that may arise during movement of information handling systems in totes or other transportation apparatuses may be reduced or eliminated.

In accordance with embodiments of the present disclosure, an apparatus may include an enclosure that includes a plurality of mounting features that are configured to receive information handling systems, a plurality of casters coupled to the enclosure, and first and second dampers. The first damper may have a first resonance frequency and be disposed such that, when the information handling systems are received in the enclosure, the first damper is coupled between the information handling systems and the plurality of casters. The second damper may have a second, different resonance frequency and be disposed such that, when the information handling systems are received in the enclosure, the second damper is coupled between the information handling systems and the plurality of casters.

In accordance with these and other embodiments of the present disclosure, a method may include forming an enclosure that includes a plurality of mounting features that are configured to receive information handling systems; coupling a plurality of casters to the enclosure; coupling a first damper having a first resonance frequency to the enclosure such that, when the information handling systems are received in the enclosure, the first damper is coupled between the information handling systems and the plurality of casters; and coupling a second damper having a second, different resonance frequency to the enclosure such that, when the information handling systems are received in the enclosure, the second damper is coupled between the information handling systems and the plurality of casters.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates a front view of an example transportation apparatus, in accordance with embodiments of the present disclosure;

FIG. 2B illustrates a side view of the embodiment of FIG. 2A;

FIG. 2C illustrates a perspective view of the embodiment of FIG. 2A;

FIG. 3 illustrates a front view of another example transportation apparatus, in accordance with embodiments of the present disclosure;

FIG. 4 illustrates a caster, in accordance with embodiments of the present disclosure;

FIG. 5 illustrates a base of an example transportation apparatus, in accordance with embodiments of the present disclosure;

FIG. 6 illustrates two different dampers arranged in parallel, in accordance with embodiments of the present disclosure; and

FIG. 7 illustrates a nonlinear damper, in accordance with embodiments of the present disclosure.

### DETAILED DESCRIPTION

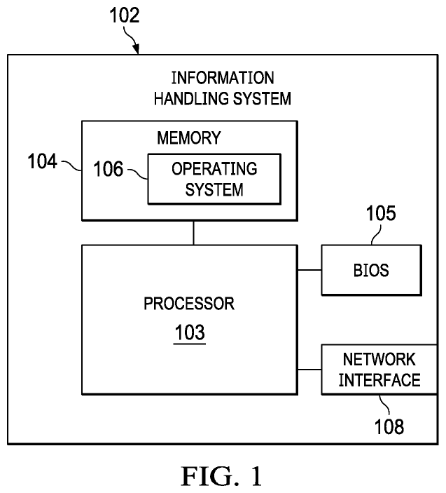

Preferred embodiments and their advantages are best understood by reference to FIGS. 1 through 7, wherein like numbers are used to indicate like and corresponding parts.

For the purposes of this disclosure, the term “information handling system” may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected directly or indirectly, with or without intervening elements.

When two or more elements are referred to as “coupleable” to one another, such term indicates that they are capable of being coupled together.

For the purposes of this disclosure, the term “computer-readable medium” (e.g., transitory or non-transitory computer-readable medium) may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; communications media such as wires, optical fibers, microwaves, radio waves, and other electromagnetic and/or optical carriers; and/or any combination of the foregoing.

For the purposes of this disclosure, the term “information handling resource” may broadly refer to any component system, device, or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources”). As shown in FIG. 1, information handling system 102 may comprise a processor 103, a memory 104 communicatively coupled to processor 103, a BIOS 105 (e.g., a UEFI BIOS) communicatively coupled to processor 103, a network interface 108 communicatively coupled to processor 103. In addition to the elements explicitly shown and described, information handling system 102 may include one or more other information handling resources.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 102 is turned off.

As shown in FIG. 1, memory 104 may have stored thereon an operating system 106. Operating system 106 may comprise any program of executable instructions (or aggregation of programs of executable instructions) configured to manage and/or control the allocation and usage of hardware resources such as memory, processor time, disk space, and input and output devices, and provide an interface between such hardware resources and application programs hosted by operating system 106. In addition, operating system 106 may include all or a portion of a network stack for network communication via a network interface (e.g., network interface 108 for communication over a data network). Although operating system 106 is shown in FIG. 1 as stored in memory 104, in some embodiments operating system 106 may be stored in storage media accessible to processor 103, and active portions of operating system 106 may be transferred from such storage media to memory 104 for execution by processor 103.

Network interface 108 may comprise one or more suitable systems, apparatuses, or devices operable to serve as an interface between information handling system 102 and one or more other information handling systems via an in-band network. Network interface 108 may enable information handling system 102 to communicate using any suitable transmission protocol and/or standard. In these and other embodiments, network interface 108 may comprise a network interface card, or “NIC.” In these and other embodiments, network interface 108 may be enabled as a local area network (LAN)-on-motherboard (LOM) card.

As discussed above, various problems are known in the art of transportation and delivery of information handling systems (e.g., information handling system 102). Accordingly, a transportation apparatus referred to herein as a tote may be used as an all-in-one solution that dampens shock events via shock absorbers and/or isolators fully integrated into a server rack, having a ship loadable design. Such a tote may be made of any suitable material (e.g., steel).

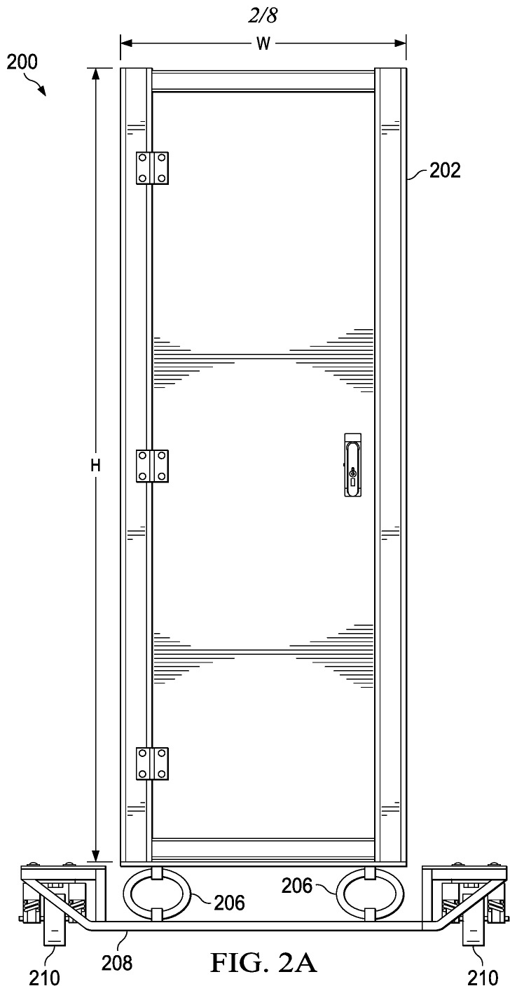

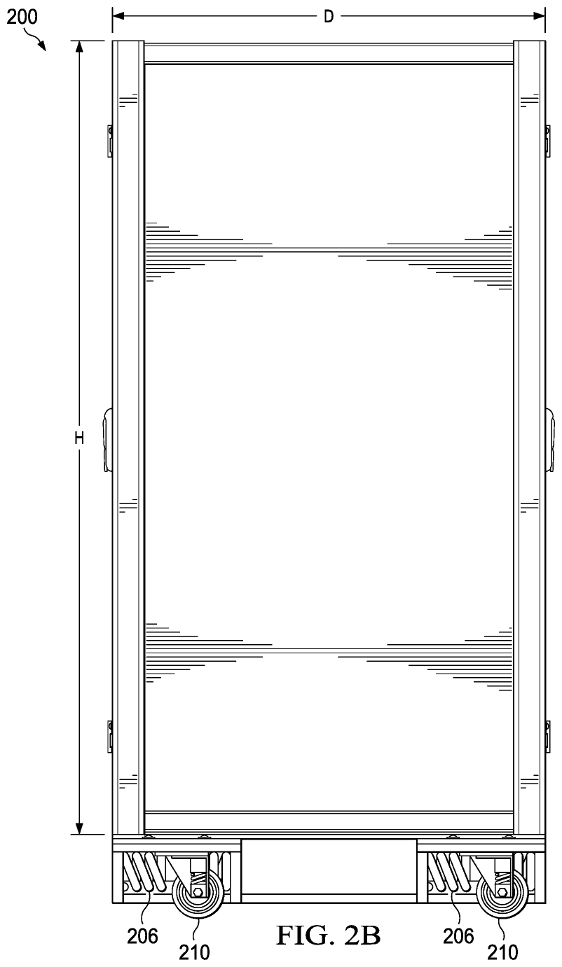

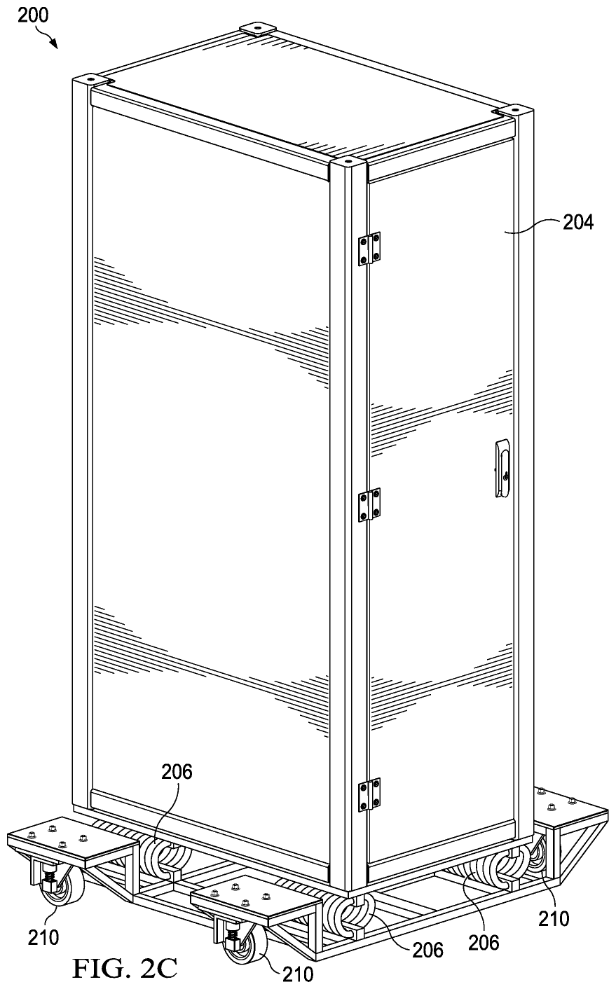

Turning now to FIGS. 2A-2C, several views are shown of an example tote 200. Tote 200 includes an enclosure portion 202 coupled on top of a base portion 208. Enclosure portion 202 may include a door 204 and a rack (not explicitly shown in these views) for receiving a plurality of information handling systems such as information handling system 102. In some embodiments, the rack may be manufactured according to a standard such as EIA-310, which defines standard rack unit sizing. For example, the embodiment shown at tote 200 may be sized to accommodate 40 rack units worth of information handling systems. In other embodiments, different sizes may be used such as 21-inch server equipment, laptops, desktops, other types of information handling systems, or information handling resources such as internet-of-things (IOT) hardware, hard drives, monitors, etc.

In some embodiments, tote 200 may be usable only for transport of information handling systems (e.g., it may not be configured for powering and operating such systems while they are received in the rack).

The rack may be isolated from vibrations during transit via the use of isolators 206. In various embodiments, isolators 206 may be wire rope, elastomeric, or any other suitable type of isolator. In the embodiment shown, isolators 206 are of the wire rope type. In some embodiments, tote 200 may also include lateral shock absorbers for protection from bumps that it may experience during integration and transportation (e.g., running into other racks, walls, truck walls, etc.).

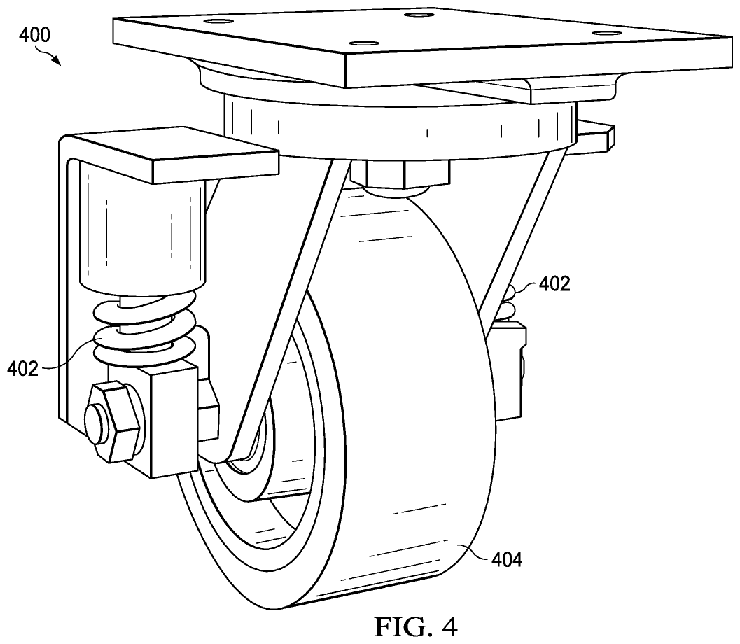

Base portion 208 may also include casters 210 (e.g., four casters 210), which may be installed in an “outrigger” configuration. For example, enclosure portion 202 has a height H, a width W, and a depth D as shown. The width and the depth may define a footprint for enclosure portion 202, and casters 210 may be disposed in positions that are laterally displaced such that they reside outside of the footprint of enclosure portion 202. In the embodiment shown, casters 210 may be shock-absorbing casters. For example, they may have integral shock dampers and/or may be mounted on shock-damping mounts. More details are described below with reference to the embodiment of FIG. 4.

The outrigger configuration for casters 210 may provide additional stability, when compared to a configuration in which casters 210 are within the footprint of enclosure portion 202 (e.g., below enclosure portion 202). Further, the displacement of casters 210 along the width direction but not along the depth direction may allow for the total depth of tote 200 may be minimized, allowing for movement through narrow doors, elevators, etc. Further, the need for pallet jacks may be eliminated.

The configuration of casters 210 and isolators 206 shown may further allow tote 200 to have a reduced total height, easing travel in constrained spaces.

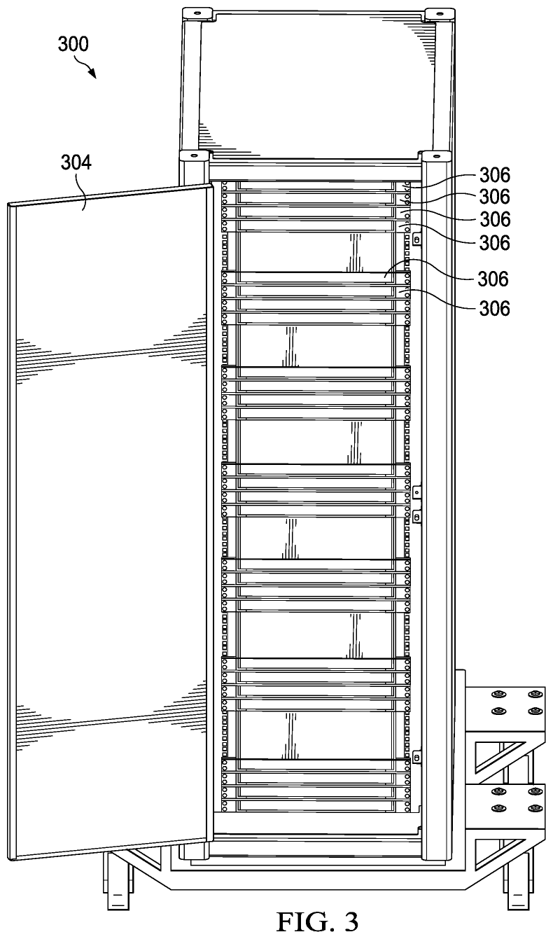

FIG. 3 shows an embodiment of a similar tote 300, in which door 304 has been opened. As can be seen in this view, a plurality of mounting features 306 are disposed within the enclosure portion of tote 300. For example, mounting features may include rails, shelves, or any other suitable hardware for securely attaching and/or retaining information handling systems.

In some embodiments, mounting features 306 may include dampers. For example, mounting features 306 may be coupled to the body of tote 300 via one or more dampers. In these and other embodiments, information handling systems may be coupled to mounting features 306 via one or more dampers interposed between the body of tote 300 and the mounting features 306.

FIG. 4 shows an embodiment of a caster 400, which may be used in some embodiments. Caster 400 includes a swivel wheel 404, as well as one or more dampers 402. In the embodiment shown, dampers 402 may comprise springs. In some embodiments, dampers 402 may be configured to engage when a large shock load is present, but configured not to engage for smaller shocks or for vibratory loads. In contrast, the isolators 206 in FIGS. 2A-2C may be configured to engage for both vibrations as well as shock loads.

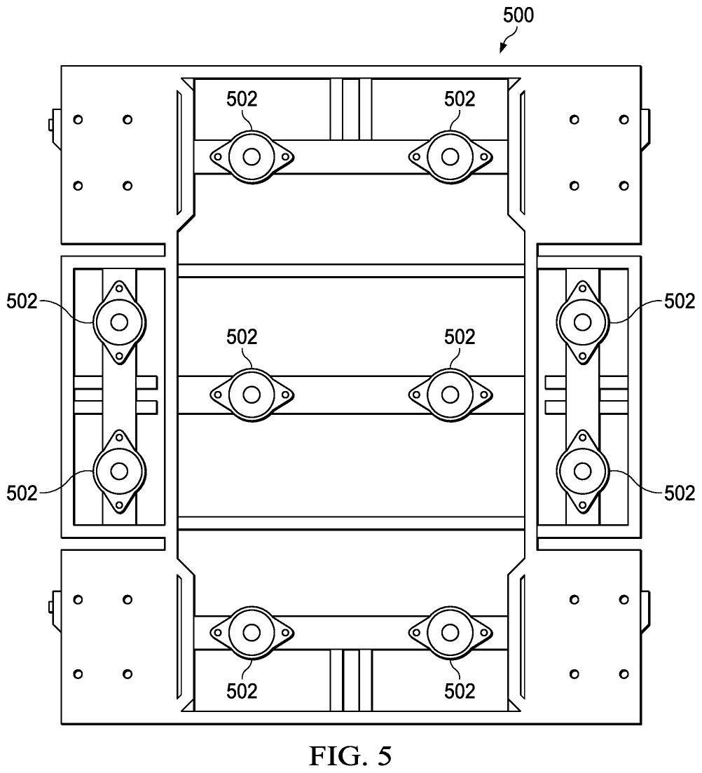

FIG. 5 shows a top view of an embodiment of a base 500 of a tote, in accordance with some embodiments of this disclosure. The enclosure portion of the tote is not shown in this view. (In this embodiment, the casters at the corners of base 500 are not arranged in the outrigger configuration of totes 200 and 300, but instead are disposed directly underneath the enclosure portion of the tote.)

Base 500 also includes a plurality of dampers 502 disposed on a top surface thereof. Dampers 502 may thus be disposed between base 500 and the enclosure portion of the tote, which may be installed on top of base 500 when the tote is fully assembled. In some embodiments, dampers 502 may comprise elastomeric isolators. In some embodiments, some of dampers 502 may be of different types, may have different resonant frequencies, may engage at different loadings, etc.

Accordingly, FIG. 5 depicts a system having two degrees of freedom. Base 500 is movable relative to the floor or ground based on the damping provided by casters, and the enclosure is also movable relative to base 500 based on the damping provided by dampers 502.

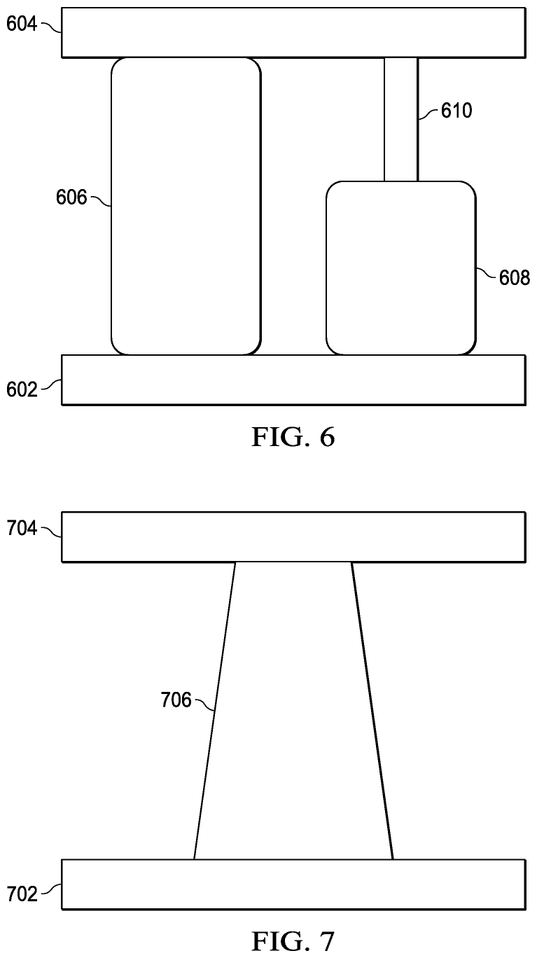

As discussed herein, even in single-DOF systems, various dampers may advantageously be used having different resonance frequencies. In various embodiments, such dampers may be arranged in parallel, in series, or in a combination thereof. FIG. 6 provides a schematic view of two dampers 606 and 608 arranged in parallel.

In the embodiment shown in FIG. 6, dampers 606 and 608 are placed between a top plate 604 and a base plate 602, resisting the compression of such plates toward one another. Damper 608 is configured with a spacer 610 such that damper 608 does not begin to engage until the two plates have already been compressed by an amount equal to the length of spacer 610. Thus, at the beginning of travel, only damper 606 may engage. After a selected amount of compression (e.g., corresponding to the length of spacer 610), both dampers 606 and 608 may engage.

In various embodiments, dampers 606 and 608 may be constructed to have similar or differing stiffnesses. For example, damper 606 may have a relatively lower stiffness (corresponding to a low resonance frequency). Damper 608 may have a relatively higher stiffness (corresponding to a higher resonance frequency).

In these and other embodiments, the arrangement of FIG. 6 may be used to provide different damping characteristics based on the loaded weight of an enclosure. For example, if an enclosure contains a relatively small mass of information handling systems and components, it may be the case that only damper 606 will be engaged during normal operation. If the enclosure contains more or heavier components, it may be the case that both dampers 606 and 608 will be engaged.

For example, it may be advantageous to increase the damping after a small deflection to change the system dynamics during an impact or vibration. Many existing systems may protect against either impacts or vibrations, but not both; the arrangement of FIG. 6 may provide for a system that protects against both impacts and vibrations by defining the response as a function of weight.

Turning now to FIG. 7, a similar embodiment is shown involving top plate 704 and base plate 702. In this embodiment, however, the two separate dampers of FIG. 6 have been replaced by a single damper 706, which is a nonlinear damper. The nonlinearity of damper 706 may be employed such that, at small deflections, the system has a relatively low stiffness (corresponding to a low resonance frequency). At larger deflections, damper 706 may exhibit a larger stiffness (corresponding to a higher resonance frequency). The nonlinearity of damper 706 may thus allow a single damper to perform similarly to the two separate dampers of FIG. 6.

Although various possible advantages with respect to embodiments of this disclosure have been described, one of ordinary skill in the art with the benefit of this disclosure will understand that in any particular embodiment, not all of such advantages may be applicable. In any particular embodiment, some, all, or even none of the listed advantages may apply.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Further, reciting in the appended claims that a structure is “configured to” or “operable to” perform one or more tasks is expressly intended not to invoke 35 U.S.C. § 112(f) for that claim element. Accordingly, none of the claims in this application as filed are intended to be interpreted as having means-plus-function elements. Should Applicant wish to invoke § 112(f) during prosecution, Applicant will recite claim elements using the “means for [performing a function]” construct.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. An apparatus comprising:
an enclosure that includes a plurality of mounting features that are configured to receive information handling systems;
a plurality of casters coupled to the enclosure;
a first damper having a first resonance frequency and disposed such that, when the information handling systems are received in the enclosure, the first damper is coupled between the information handling systems and the plurality of casters; and
a second damper having a second, different resonance frequency and disposed such that, when the information handling systems are received in the enclosure, the second damper is coupled between the information handling systems and the plurality of casters.

2. The apparatus of claim 1, wherein the enclosure and the mounting features are sized to receive information handling systems that conform to standardized rack unit sizes.

3. The apparatus of claim 1, wherein the first and second dampers are coupled in parallel between the enclosure and the plurality of casters.

4. The apparatus of claim 1, wherein the first and second dampers are coupled in series between the enclosure and the plurality of casters.

5. The apparatus of claim 1, wherein the first and second dampers are respective portions of a single, nonlinear damper.

6. The apparatus of claim 1, further comprising a base coupled between the casters and the enclosure.

7. The apparatus of claim 6, wherein:
the first damper is coupled between the enclosure and the base; and
the second damper is coupled between the base and the plurality of casters.

8. The apparatus of claim 1, wherein the plurality of mounting features include mounting rails.

9. The apparatus of claim 8, wherein:
the first damper is coupled between the enclosure and the mounting rails; and
the second damper is coupled between the enclosure and the plurality of casters.

10. The apparatus of claim 1, wherein the apparatus is configured for transportation of the information handling systems, but is not configured to allow for operation of the information handling systems while the information handling systems are received therein.

11. The apparatus of claim 1, wherein the first and second dampers are configured such that:
at a first impact or vibrational load, the first damper is configured to provide damping, and the second damper is configured not to provide damping.

12. The apparatus of claim 11, wherein the first and second dampers are further configure such that:
at a second, greater impact or vibrational load, the first and second dampers are both configured to provide damping.

13. A method comprising:
forming an enclosure that includes a plurality of mounting features that are configured to receive information handling systems;
coupling a plurality of casters to the enclosure;
coupling a first damper having a first resonance frequency to the enclosure such that, when the information handling systems are received in the enclosure, the first damper is coupled between the information handling systems and the plurality of casters; and
coupling a second damper having a second, different resonance frequency to the enclosure such that, when the information handling systems are received in the enclosure, the second damper is coupled between the information handling systems and the plurality of casters.

14. The method of claim 13, wherein the enclosure and the mounting features are sized to receive information handling systems that conform to standardized rack unit sizes.

15. The method of claim 13, wherein the first and second dampers are coupled in parallel between the enclosure and the plurality of casters.

16. The method of claim 13, wherein the first and second dampers are coupled in series between the enclosure and the plurality of casters.

17. The method of claim 13, wherein the first and second dampers are respective portions of a single, nonlinear damper.

18. The method of claim 13, further comprising coupling a base between the enclosure and the plurality of casters.

19. The method of claim 18, wherein:
the first damper is coupled between the enclosure and the base; and
the second damper is coupled between the base and the plurality of casters.

20. The method of claim 13, further comprising:
loading a plurality of information handling systems into the enclosure;
transporting the enclosure from a first location to a second location;
unloading the plurality of information handling systems from the enclosure; and
reusing the enclosure by loading a second, different plurality of information handling systems into the enclosure.
